(19) United States
(12) Patent Application Publication
(10) Pub. No.: US 2009/0258169 A1
(43) Pub. Date: Oct. 15, 2009

(54) METHOD FOR MANUFACTURING A PATTERNED METAL LAYER

(76) Inventors: Chin-Lung LIAO, Tainan County (TW); Jia-Chong Ho, Hsinchu County (TW)

Correspondence Address: BIRCH STEWART KOLASCH & BIRCH, PO BOX 747, FALLS CHURCH, VA, 22040-0747, US

(21) Appl. No.: 12/336,162

(22) Filed: Dec. 16, 2008

(30) Foreign Application Priority Data
Apr. 9, 2008 (TW) 97112790

(51) Int. Cl. B41M 5/26; C23C 26/00; H01L 21/84; H01L 21/02

(52) U.S. Cl. 427/597; 438/151; 438/99; 257/E21.002; 257/E21.411

(57) ABSTRACT

This invention provides a method for manufacturing a patterned metal layer, which forms a metal layer on a sacrificial layer having light-thermal conversion characteristic on a first substrate. The metal layer is patterned onto a second substrate by a laser transfer printing method to form a patterned metal layer on the second substrate. The sacrificial layer between the patterned metal layer and the first substrate can absorb laser light to protect the patterned metal layer from absorbing laser light and being heated. The oxidation of the patterned metal layer is prohibited.

### BACKGROUND OF THE INVENTION

1. Field of the Invention

The present invention relates to a method for fabricating a patterned metal layer. More particularly, the present invention relates to a method for fabricating a patterned metal layer employing a laser transfer technology.

2. Description of the Related Art

As the technology becoming mature, the display devices being flexible, lighter, thinner and portable such as electronic papers have already attracted many people's attention. Lots of companies are committed to research and development in this area. The organic thin film transistor is a kind of transistor employing organic material and applicable in various electronic devices. The greatest advantage is the organic thin film transistor can be fabricated at a low temperature, and whose characteristics still can be maintained to keep the normal display performance even the display panel is bended. This application would facilitate the flexible electronic devices such as display being realized. The electrode pattern of the top-contact-type organic thin film transistor is made by using a shadow mask. There is a problem of high cost for the shadow mask and for the manufacturing process. Moreover, as increasingly miniaturization of the electronic devices, the fabrication of the metal electrodes of the thin film transistors also encountered challenge. The laser transfer printing method can directly transfer the patterned metal layer, whose manufacturing process is simple and without a need of the shadow mask. In addition, the laser transfer printing method has a low cost and is capable of producing the patterned layer in a large area scale. It is a large demand for how to apply the laser transfer printing technology in the fabrication of the patterned metal layers of various electronic devices.

### SUMMARY OF THE INVENTION

The present invention provides a method for manufacturing a patterned metal layer, which employs a laser transfer printing method to form a patterned metal layer on a substrate, and a sacrificial layer having a light-thermal conversion characteristic is added between the metal layer to be transferred and a supporting substrate, by the sacrificial layer absorbing laser light to proceed light-thermal conversion and releasing from the supporting substrate, the metal laser is patterned and transferred unto the substrate, and hence protecting the patterned metal layer from absorbing the laser light and being heated, the oxidation of the patterned metal layer is avoided.

The present invention provides a method for manufacturing a patterned metal layer suitable for fabricating gate electrodes, source/drain electrodes or conductive wire patterns of thin film transistors or metal electrodes of light-emitting diode devices.

The present invention provides a method for manufacturing a patterned metal layer, comprising providing a first substrate having a sacrificial layer formed thereon, in which the sacrificial layer has a light-thermal conversion characteristic; forming a metal layer on the sacrificial layer; placing the first substrate upside down over a second substrate so that the metal layer approximates to or contacts the second substrate; performing a laser transfer printing method to pattern the metal layer onto the second substrate; removing the first substrate; and removing a residue of the sacrificial layer on the patterned metal layer.

The present method for manufacturing a patterned metal layer does not need to perform the process in vacuum and require vacuum equipment as well. The process of the present method is simplified and the un-transferred metal layer can be used again to save the cost of the material.

The present invention also provides a method for manufacturing a thin film transistor, comprising providing a first substrate having a sacrificial layer formed thereon, in which the sacrificial layer has a light-thermal conversion characteristic; forming a metal layer on the sacrificial layer; placing the first substrate upside down over the second substrate so that the metal layer approximates to or contacts the second substrate; performing a first laser transfer printing method to pattern the metal layer onto the second substrate to form a gate electrode pattern on the second substrate; removing the first substrate; removing a residue of the sacrificial layer on the gate electrode pattern; forming a patterned insulating layer on the gate electrode pattern, wherein a portion of the patterned insulating layer is served as a gate insulating layer; repeating the above first to third steps and performing a second laser transfer printing method to form a metal wire pattern on the patterned insulating layer; removing the first substrate; removing a residue of the sacrificial layer on the metal wire pattern; forming a patterned semiconductor active layer on the patterned insulating layer, the patterned semiconductor active layer corresponding to the gate electrode pattern; repeating the above first to third steps and performing a third laser transfer printing method to form a source/drain pattern on the patterned semiconductor active layer; removing the first substrate; and removing a residue of the sacrificial layer on the source/drain pattern.

The present method for manufacturing the thin film transistor employs a single laser transfer printing process to fabricate metal gate electrodes, source/drain electrodes and metal wires. The manufacturing process is simplified and also suitable for fabricating devices in large-area scale. The cost down of manufacturing the devices is attained.

### BRIEF DESCRIPTION OF THE DRAWINGS

FIG. 1 is a process flow of a method for fabricating a patterned metal layer of the present invention; and

FIG. 2A to FIG. 2L shows structurally schematic cross-sectional views of a method for fabricating thin film transistors of the present invention.

### DETAILED DESCRIPTION OF THE PREFERRED EMBODIMENTS

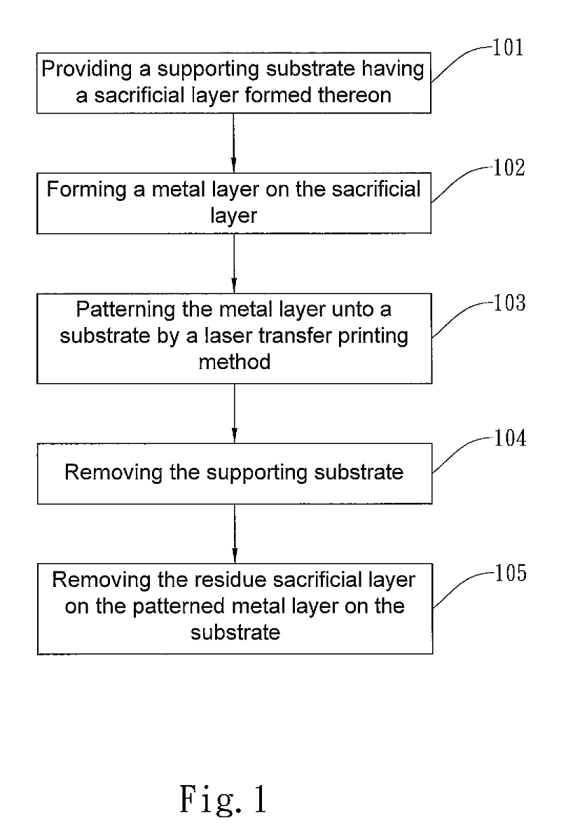

FIG. 1 shows a process flow of a method for manufacturing a patterned metal layer of the present invention. In step 101, firstly, a supporting substrate having a sacrificial layer formed thereon is provided. The supporting substrate is transparent, such as a glass substrate. The sacrificial layer has a light-thermal conversion characteristic, which is capable of absorbing laser light with a specific wavelength to convert the absorbed laser light to heat. Portions of the sacrificial layer are heated and molten to release from the supporting substrate. The sacrificial layer can be poly(vinylalcohol) (PVA). In step 102, forming a metal layer on the sacrificial layer, for example by vapor deposition or sputtering. In step 103, the supporting substrate is placed over a substrate in a way that the surface of the supporting substrate having the metal layer is upside down and the metal layer approximates to the substrate by way of placing a plurality of spacers between the supporting substrate and the substrate to keep the supporting substrate being placed over the nearby of the substrate, or the metal layer directly contacts the substrate. The substrate can be a flexible substrate. A multiple of laser beams are projected upon a surface of the supporting substrate opposite to the surface of the supporting substrate having the metal layer formed thereon. The traveling path of the laser beams is predetermined depending on a pattern of the metal layer to be transferred unto the substrate and controlled by a computer. The laser beams pass through the supporting substrate and are absorbed by specific portions of the sacrificial layer, and being converted to heat energy. The specific portions of the sacrificial layer are heated and molten to release from the supporting substrate. Portions of the metal layer combined with the molten portions of the sacrificial layer are directly transferred unto the substrate. In the present invention, the traveling path of the laser beams can be predetermined by a computer depending on a pattern of the metal layer to be transferred onto the substrate. The patterned metal layer can be transferred unto the substrate by the laser transfer printing method. Then, in step 104, the supporting substrate is removed. Finally, in step 105, a residue of the sacrificial layer on the patterned metal layer on the substrate is removed, for example with solvent.

In the present method, the laser light is absorbed by the sacrificial layer between the supporting substrate and the metal layer to be transferred, and being converted to heat energy. The metal layer to be transferred is protected by the sacrificial layer and is prevented from being illuminated by the laser beams. The method of the present invention can prevent the metal layer to be patterned and transferred from absorbing the laser light and being heated. The oxidation of the patterned metal layer is avoided. In addition, the present invention employs the laser transfer printing method to directly fabricate the patterned metal layer without performing the process in vacuum or using the vacuum equipment so as to significantly reduce the expense of the fabrication machine. Besides, the present invention employs the laser transfer printing method to fabricate the patterned metal layer at a low temperature such that the present method can be applicable in the fabrication of flexible electronic devices. The laser transfer printing method of the present invention employs multiple laser beams, which is also suitable for the fabrication of the devices in a large-area scale.

The method for manufacturing a patterned metal layer of the present invention as described above is applicable in producing gate electrodes, source/drain electrodes or other conductive wire patterns of a thin film transistor, or being applicable in producing cathode and anode electrodes of a light-emitting diode device. The fabrication of the gate electrodes, the source/drain electrodes and the conductive wire pattern of the thin film transistor by the present method as described above is illustrated and described in the following.

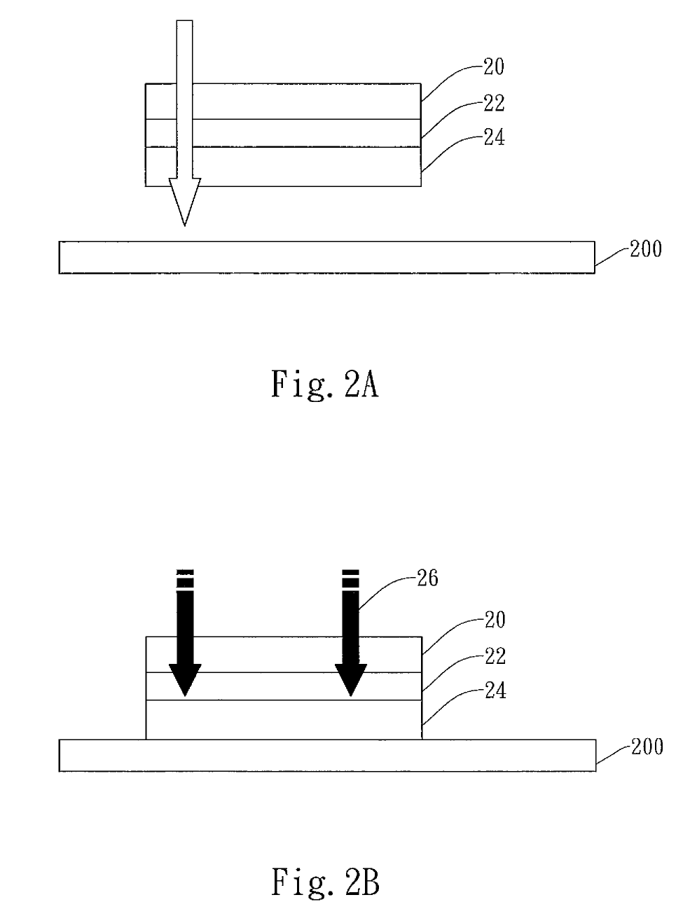

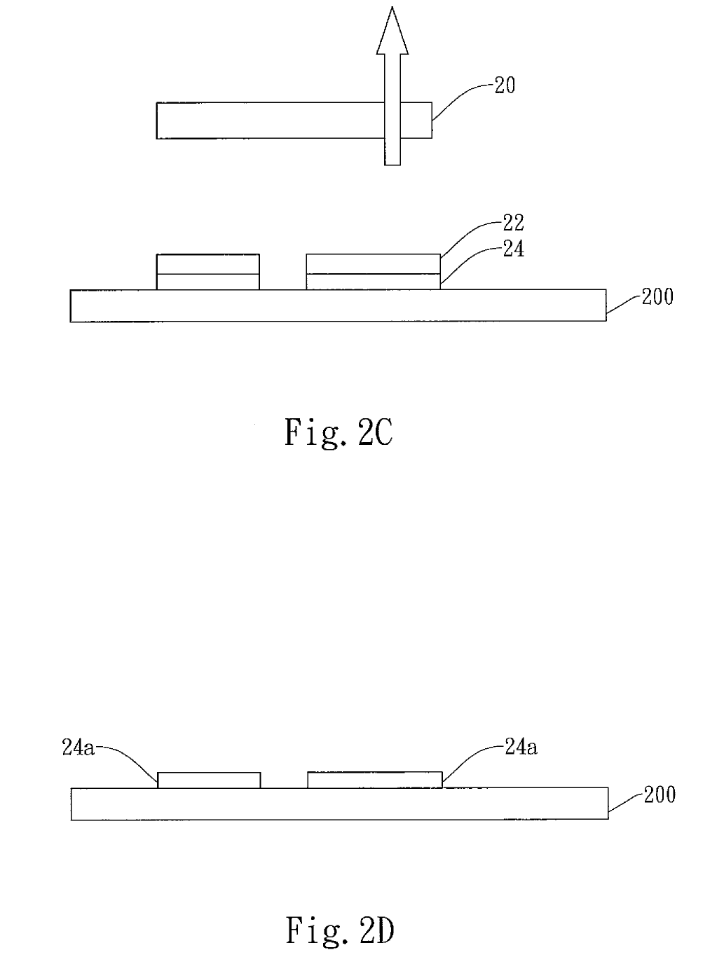

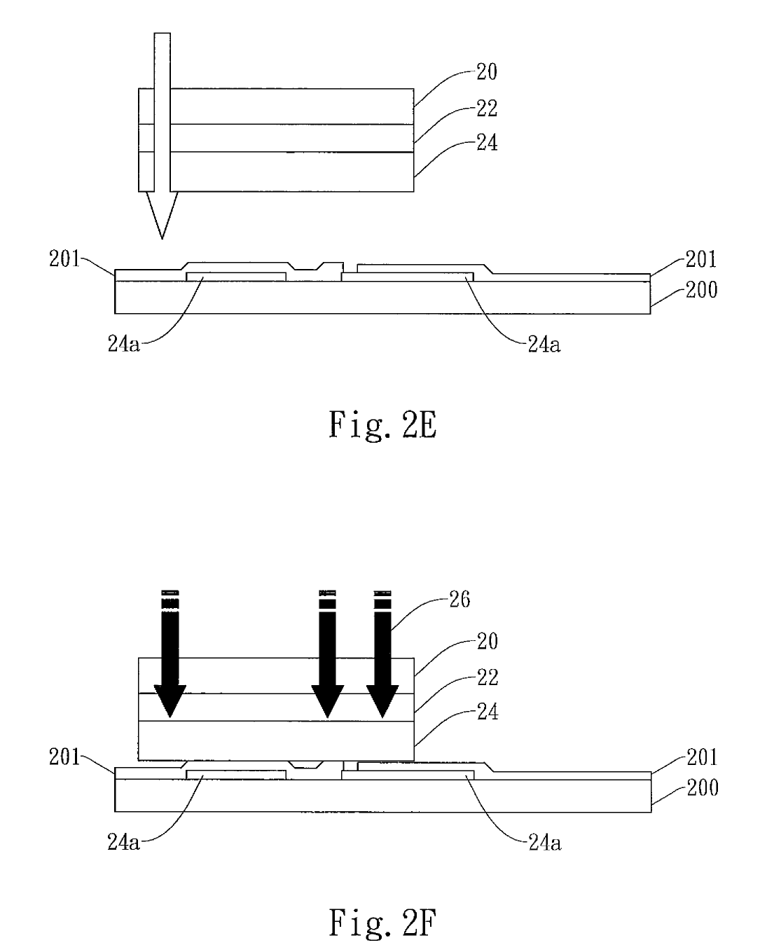

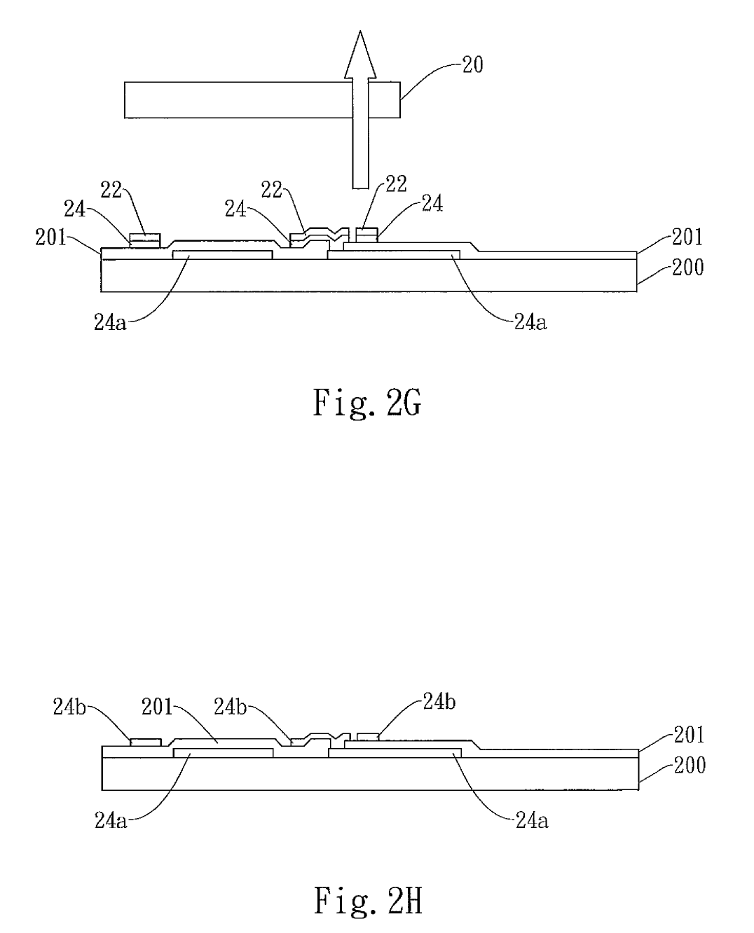

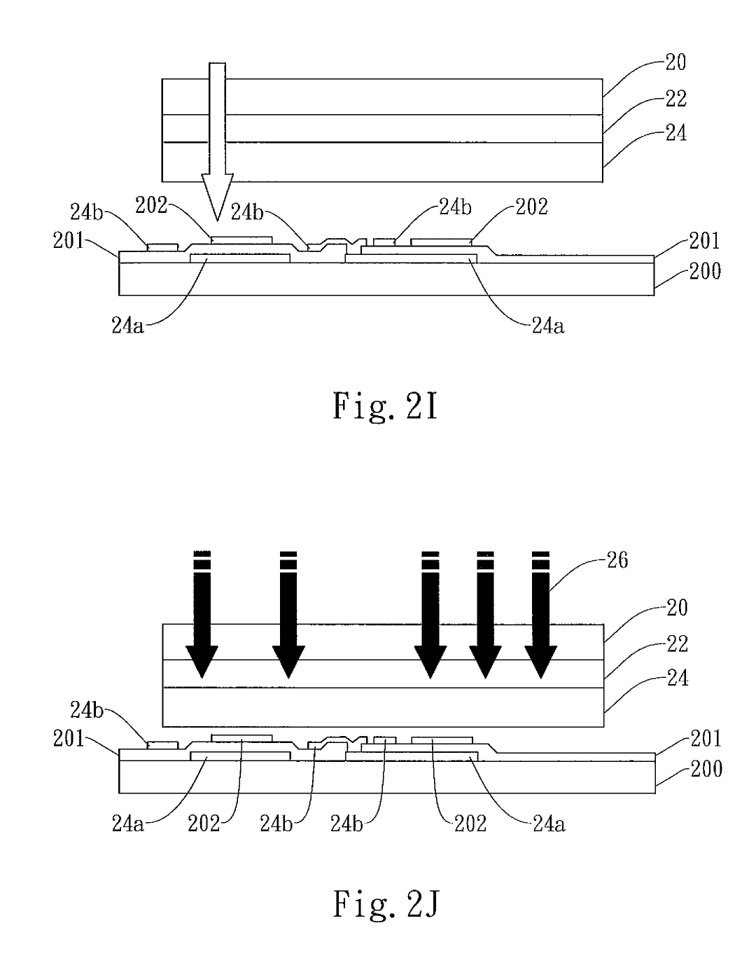

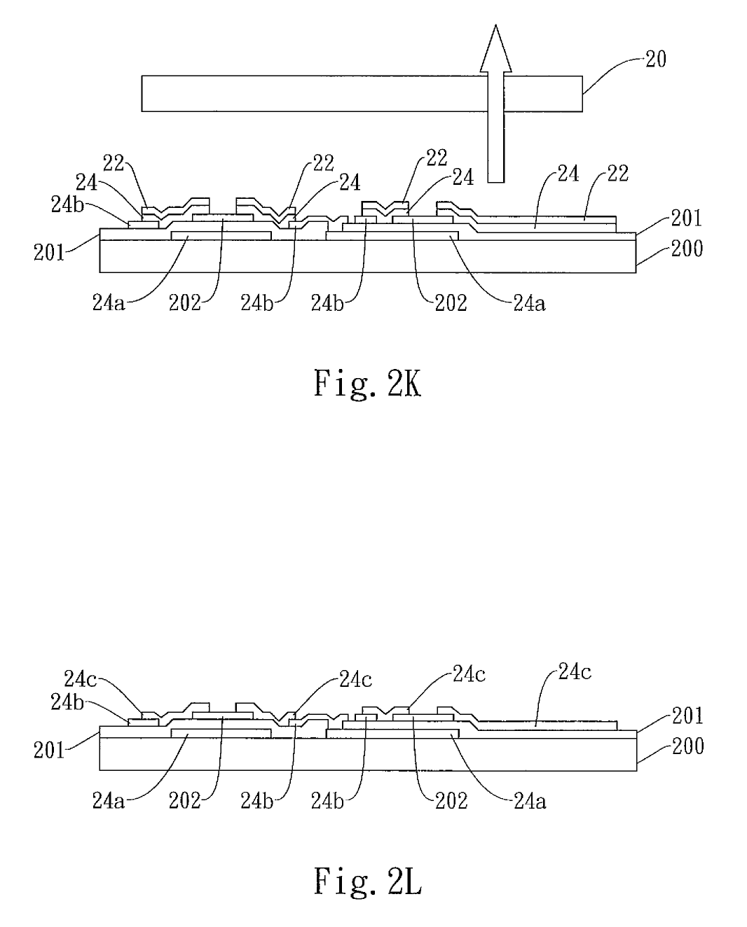

FIGS. 2A through 2D are structurally schematic cross-sectional views corresponding to various stages for fabricating the gate electrode pattern of the thin film transistors. Referring to FIG. 2A, firstly a transparent first substrate 20, such as a glass substrate is provided. The first substrate 20 has a sacrificial layer 22 having a light-thermal conversion characteristic formed thereon. The sacrificial layer 22 can absorb the laser light with a specific wavelength, and converting the laser light to heat energy. The portions of the sacrificial layer 22 absorbing the laser light are heated and molten, and releasing from the first substrate 20. The sacrificial layer 22 can be poly(vinylalcohol)(PVA). A metal layer 24 is formed on the sacrificial layer 22, for example by vapor deposition or sputtering. The first substrate 20 with the surface having the metal layer 24 upside down is placed over the second substrate 200. Referring to FIG. 2B, for example, the first substrate 20 directly contacts the second substrate 200. Then, the multiple laser beams 26 are projected unto a surface of the first substrate 20 opposite to the metal layer 24. The traveling path of the laser beams 26 are predetermined depending on the gate electrode pattern to be fabricated and controlled by a computer. Referring to FIG. 2C, the laser beams 26 pass through the first substrate 20 and are absorbed by portions of the sacrificial layer 22 corresponding to the gate electrode pattern, and being converted to heat energy. The portions of the sacrificial layer 22 absorbing the laser light are heated and molten, and releasing from the first substrate 20. As a consequence, the sacrificial layer 22 and the metal layer 24 forming the gate electrode pattern are transferred unto the second substrate 200. Referring to FIG. 2D, the first substrate 20 is removed from the above of the second substrate 200. The residue of the sacrificial layer 22 left on the patterned metal layer 24 on the second substrate 200 is removed with solvent. As a consequence, a gate electrode pattern 24a is fabricated on the second substrate 200.

FIGS. 2E through 2H are structurally schematic cross-sectional views corresponding to various stages for fabricating the metal wire pattern of the thin film transistors. Referring to FIG. 2E, forming a patterned insulating layer 201 on the gate electrode pattern 24a, in which a portion of the patterned insulating layer 201 is served as a gate insulating layer of the thin film transistors subsequently completed. Similarly, a first substrate 20 having the sacrificial layer 22 and the metal layer 24 formed thereon is firstly provided. The first substrate 20 with the surface having the metal layer 24 upside down is placed on the second substrate 200. In this fabrication stage, the material of the metal layer to be patterned and transferred can be different from that of the gate electrode pattern 24a. In other words, another kind of metal layer can be formed on the sacrificial layer 22 of the first substrate 20 by vapor deposition or sputtering to be served as the metal layer to be patterned and transferred. Referring to FIG. 2F, the first substrate 20 directly contacts the second substrate 200. A multiple of laser beams 26 is projected unto a surface of the first substrate 20 opposite to the metal layer 24. The traveling path of the laser beams are predetermined depending on the metal wire pattern to be fabricated and controlled by a computer. Referring to FIG. 2G, the multiple laser beams pass through the first substrate 20 and are absorbed by portions of the sacrificial layer 22 corresponding to the metal wire pattern, and being converted to heat. The portions of the sacrificial layer 22 absorbing the laser light are heated and molten, and releasing from the first substrate 20. As a consequence, the sacrificial layer 22 and the metal layer 24 forming the metal wire pattern are patterned and transferred unto the second substrate 200. Referring to FIG. 2H, the first substrate 20 is removed from the above of the second substrate 200. The residue of the sacrificial layer 22 left on the patterned metal layer 24 on the second substrate 200 is removed with solvent. As a consequence, a metal wire pattern 24b is fabricated on the second substrate 200.

FIGS. 2I through 2L are structurally schematic cross-sectional views corresponding to various stages for fabricating the source/drain pattern of the thin film transistors. Referring to FIG. 2I, a patterned semiconductor active layer 202 is formed on the patterned insulating layer 201. The patterned semiconductor active layer 202 corresponds to the gate electrode pattern 24a. The patterned semiconductor active layer 202 can be formed of organic material. Similarly, a first substrate 20 with the sacrificial layer 22 and the metal layer 24 formed thereon is provided. The first substrate 20 is placed over the second substrate 200 in a way of the surface of the first substrate 20 having the metal layer 24 being upside down. In the fabricating stage, the material of the metal layer to be transferred can be different from that of the gate electrode pattern 24a or the metal wire pattern 24b. In other words, another kind of metal layer can be formed on the sacrificial layer 22 by vapor deposition or sputtering to be served as the metal layer to be transferred. Referring to FIG. 2J, making the first substrate 20 approximate to the second substrate 200, for example a plurality of spacers are interposed between the first substrate 20 and the second substrate 200 to support the first substrate 200 over the second substrate 200. Continually, a plurality of laser beams 26 are projected upon a surface of the first substrate 20 opposite to the metal layer 24. The traveling path of the laser beams 26 are determined and controlled by a computer depending on the source/drain pattern to be fabricated. Referring to FIG. 2K, the laser beams 26 pass through the first substrate 20 and are absorbed by specific portions of the sacrificial layer 22 corresponding to the source/drain pattern, and being converted to heat energy. The specific portions of the sacrificial layer 22 are heated and molten, and releasing from the first substrate 20. As a consequence, the sacrificial layer 22 and the metal layer 24 forming the source/drain pattern are transferred unto the second substrate 200. Referring to FIG. 2L, the first substrate 20 is removed from the above of the second substrate 200. The residue of the sacrificial layer 22 left on the metal layer 24 over the second substrate 200 is removed with solvent. As a consequence, the source/drain pattern 24c is fabricated over the second substrate 200.

The rest of the metal layer 24 untransferred and left on the first substrate 20 after completion of each of the manufacturing processes respectively for fabricating the gate electrode pattern, the source/drain pattern and the conductive wire pattern can be used again in the next manufacturing process. The present method can save the material cost. In addition, the present invention employs the laser transfer printing method to form the patterned metal layers, whose process temperature is low and thus suitable for the fabrication of the flexible electronic devices.

While the invention has been described by way of examples and in terms of preferred embodiments, it is to be understood that various changes, substitutions, and alterations can be made herein without departing from the spirit and scope of the invention as defined by the appended claims.

What is claimed is:

1. A method for manufacturing a patterned metal layer, comprising:
providing a first substrate having a sacrificial layer formed thereon, said sacrificial layer having a light-thermal conversion characteristic;
forming a metal layer on said sacrificial layer;
placing said first substrate upside down over a second substrate so that said metal layer approximates to or contacts said second substrate;
performing a laser transfer printing method to pattern said metal layer onto said second substrate;
removing said first substrate; and
removing a residue of said sacrificial layer on said patterned metal layer.

2. The method of claim 1, wherein said sacrificial layer comprises poly(vinylalcohol).

3. The method of claim 1, wherein the step of performing the laser transfer printing method comprises controlling traveling path of multiple laser beams by a computer and the traveling path of the multiple laser beams is determined by a pattern of said metal layer to be transferred unto said second substrate.

4. The method of claim 1, wherein a plurality of spacers is disposed between said first substrate and said second substrate.

5. The method of claim 1, wherein said metal layer is formed on said sacrificial layer by vapor deposition or sputtering.

6. The method of claim 2, wherein the residue of said sacrificial layer is removed from said second substrate with solvent.

7. The method of claim 1, wherein said second substrate is a flexible substrate.

8. A method for manufacturing a thin film transistor, comprising:
providing a first substrate having a sacrificial layer formed thereon, said sacrificial layer having a light-thermal conversion characteristic;
forming a metal layer on said sacrificial layer;
placing said first substrate upside down over said second substrate so that said metal layer approximates to or contacts said second substrate;
performing a first laser transfer printing method to pattern said metal layer onto said second substrate to form a gate electrode pattern on said second substrate;
removing said first substrate;
removing a residue of said sacrificial layer on said gate electrode pattern;
forming a patterned insulating layer on said gate electrode pattern, wherein a portion of said patterned insulating layer is served as a gate insulating layer;
repeating aforesaid first to third steps and performing a second laser transfer printing method to form a metal wire pattern on said patterned insulating layer;
removing said first substrate;
removing a residue of said sacrificial layer on said metal wire pattern;
forming a patterned semiconductor active layer on said patterned insulating layer, said patterned semiconductor active layer corresponding to said gate electrode pattern;
repeating aforesaid first to third steps and performing a third laser transfer printing method to form a source/drain pattern on said patterned semiconductor active layer;
removing said first substrate; and
removing a residue of said sacrificial layer on said source/drain pattern.

9. The method of claim 8, wherein said sacrificial layer comprises poly(vinylalcohol).

10. The method of claim 8, wherein the steps of performing said first, second and third laser transfer printing methods comprise controlling traveling path of multiple laser beams by a computer and the traveling path of the multiple laser beams in said first laser transfer printing method is determined by said gate electrode pattern, the traveling path of the multiple laser beams in said second laser transfer printing method is determined by said metal wire pattern, and the traveling path of the multiple laser beams in said third laser transfer printing method is determined by said source/drain pattern.

11. The method of claim 8, wherein a plurality of spacers is disposed between said first substrate and said second substrate.

12. The method of claim 8, wherein said metal layer is formed on said sacrificial layer by vapor deposition or sputtering.

13. The method of claim 8, wherein the residue of said sacrificial layer on said second substrate is removed with solvent.

14. The method of claim 8, wherein said patterned semiconductor active layer comprises organic material.

15. The method of claim 8, wherein said second substrate is a flexible substrate.
